(19) United States
(12) Patent Application Publication
(10) Pub. No.: US 2026/0147034 A1
(43) Pub. Date: May 28, 2026

(54) CONTACTLESS ELECTRICAL INSPECTION PROCESS

(71) Applicant: Taiwan Semiconductor Manufacturing Company, Ltd., Hsinchu (TW)

(72) Inventors: Mill-Jer Wang, Hsinchu (TW); Zhihua Zou, Hsinchu (TW); Ting-Pu Tai, Hsinchu (TW); Kam Heng Lee, Hsinchu City (TW)

(73) Assignee: Taiwan Semiconductor Manufacturing Company, Ltd., Hsinchu (TW)

(21) Appl. No.: 18/956,017

(22) Filed: Nov. 22, 2024

(51) Int. Cl. G01R 31/28; G01R 31/307; H01L 21/66

(52) U.S. Cl. CPC G01R 31/2853; G01R 31/307; H10P 74/203

(57) ABSTRACT

A method including the following steps is provided: providing a first electronic component; providing a second electronic component; performing a bonding process to bond the first electronic component and the second electronic component; and performing an inspection process during or after the bonding process, wherein the inspection process includes a contactless inspection process.

### BACKGROUND

A contact-based electrical inspection process is often performed by using a probe pin or a probe card with a plurality probe pins. However, the contact-based electrical inspection process has many restrictions or limitations. For example, the size of the area to be contacted may be more than 45 micrometers (μm) and there will be a minimum size limit between the two probe pins due to the probe pin size.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A illustrates a side sectional view of a portion of an electronic component of the disclosure.

FIG. 1B illustrates a side sectional view of a portion of an electronic component of the disclosure.

FIG. 1C illustrates a side sectional view of a portion of an electronic component of the disclosure.

FIG. 2A illustrates a top view of a portion of an electronic component of the disclosure.

FIG. 2B illustrates a top view of a portion of an electronic component of the disclosure.

FIGS. 3A and 3B illustrate side sectional views of a portion of an electronic package manufacturing process of the disclosure.

FIGS. 4A and 4B illustrate top views of a portion of an electronic package manufacturing process of the disclosure.

FIG. 5 illustrates a top view of an electronic package of the disclosure.

FIGS. 6A to 6D illustrate perspective views of a portion of an electronic package of the disclosure.

FIG. 7 illustrates a portion of flow for a manufacturing method of an electronic component of the disclosure.

### DETAILED DESCRIPTION

The following disclosure provides many different embodiments or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the component in use or operation in addition to the orientation depicted in the figures. The apparatus may be otherwise oriented (rotated 90 degrees or at other orientations) and the spatially relative descriptors used herein may likewise be interpreted accordingly.

It will be understood that, although the terms “first”, “second”, “third” and the like, may be used herein to describe various elements, these elements should not be limited by these terms. These terms are only used to distinguish one element from another. For example, a first element may be referred to as a second element, and similarly, a second element may be referred to as a first element without departing from the scope of protection of the inventive concept.

Semiconductor fabrication generally involves the formation of electronic circuits by performing multiple deposition processes, etching processes, annealing processes, and/or implantation processes of material layers, whereby a stack structure including many semiconductor devices and interconnects between is formed. Dimension scaling (down) is one technique employed to fit ever greater numbers of semiconductor devices in the same area. However, dimension scaling may become increasingly difficult in advanced technology nodes. For example, the size of the conductive terminals (e.g., bumps or pads) is smaller; or, the spacing between the conductive terminals is reduced, so an open/closed circuit testing may be more difficult by using a contact-based method (e.g., a probe card test or a probe pin test).

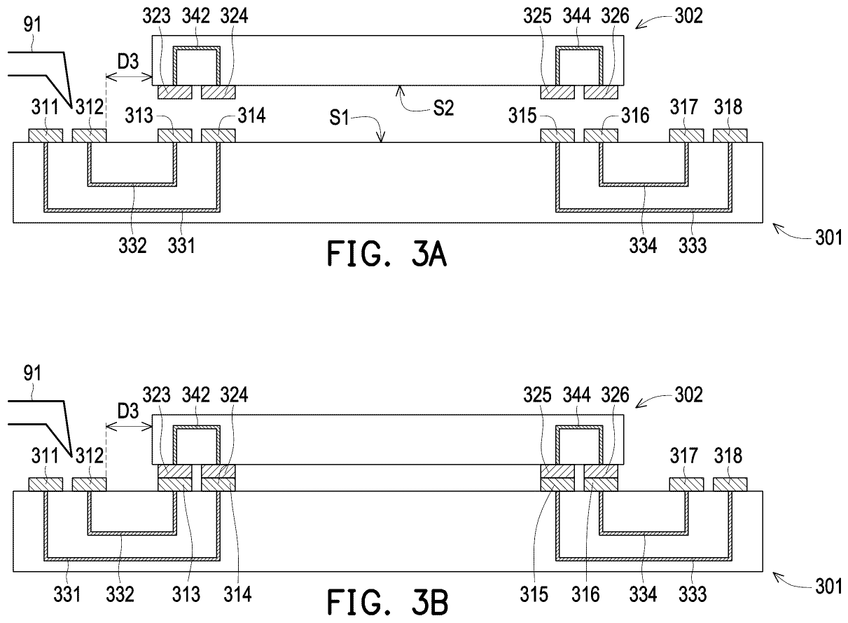

In embodiments of the present disclosure, an electron beam inspection (E-beam inspection, EBI) could be performed on one or more metal layers of an electronic component (e.g., a semiconductor component) by using a scanning electron microscopy (SEM) in a low-pressure (gas pressure less than or approximately equal to 100 Pa) chamber or a vacuum (gas pressure less than or approximately equal to 0.00001 Pa) chamber, to confirm whether the circuits thereof are open, short, break, or leakage. Briefly, an electron beam with high-energy electrons could be provided by an electron beam apparatus (e.g., the electron beam apparatus 91 as shown in FIGS. 3A and/or 3B or other similar drawing, for example, an electron gun of an electronic beam inspection system), and the electron beam is directed toward one or more corresponding exposed conductors of the electronic component to produce secondary electrons and/or backscattered electrons. Secondary electrons tend to reflect off the surface of the sample (e.g., the surface of the exposed conductor which the electron beam is directed toward) and have low energy levels. Backscattered electrons could penetrate into the sample, and could further flow elsewhere through corresponding one or more circuits electrically connected thereto. Then, the electronic component is scanned to obtain an inspecting image. Based on the gray level of the inspecting image, comparison and identification (e.g., computer vision comparison and identification) is performed to identify abnormalities (if any) in the inspecting image, which are regarded as electrical defects, for example, in a positive potential mode (e.g., positive model), a bright spot may be indicated that a circuit of the electronic component under test is short circuit (short) or leakage (leakage), and a dark spot may be indicated that a circuit of the electronic component under test is open circuit (open) or break (break).

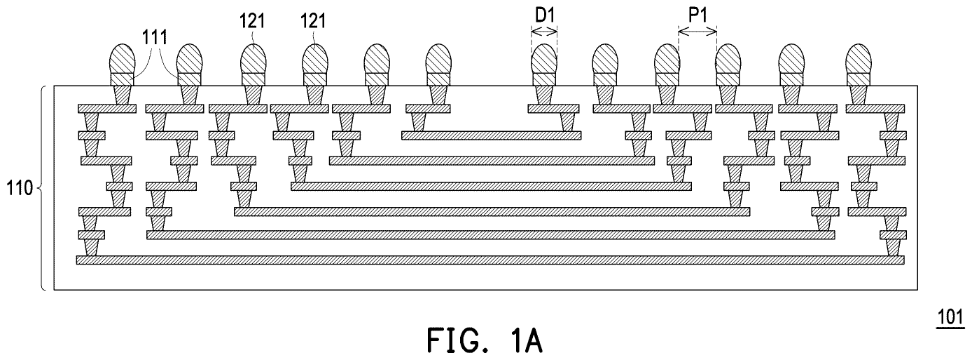

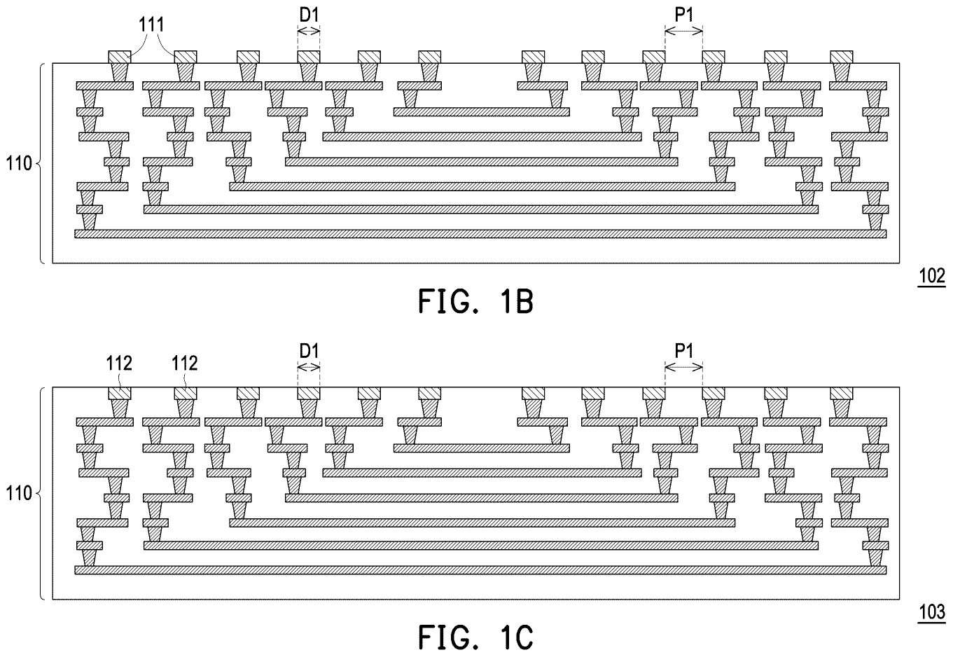

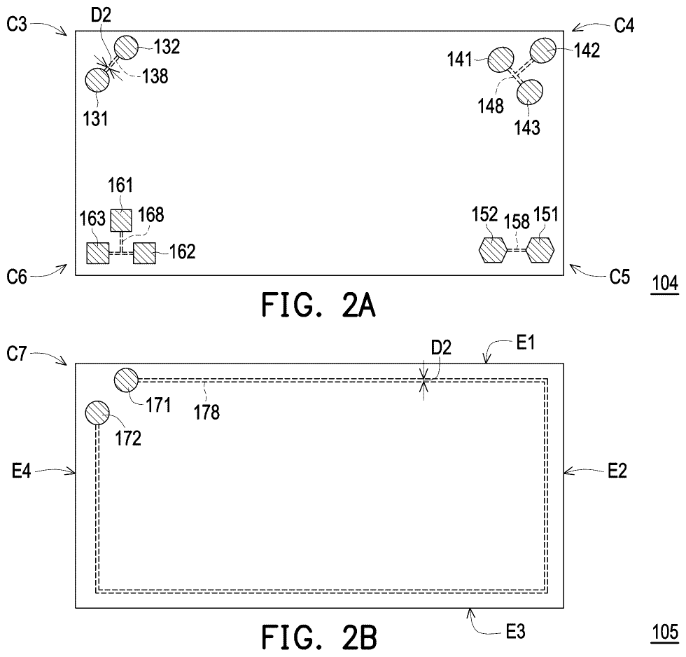

FIGS. 1A, 1B and/or 1C illustrate side sectional views of a portion of corresponding electronic components could be inspected of the disclosure. FIGS. 2A and/or 2B illustrate top views of a portion of corresponding electronic components could be inspected of the disclosure. In an embodiment, the electronic component 101 as shown in FIG. 1A, the electronic component 102 as shown in FIG. 1B, the electronic component 103 as shown in FIG. 1C, the electronic component 201 as shown in FIG. 2A, and/or the electronic component 202 as shown in FIG. 2B may be a portion of a wafer (e.g., a semiconductor wafer) or a substrate (e.g., a glass substrate, a laminated substrate (e.g., an FR4 substrate)) having corresponding circuits.

For example, as shown in FIG. 1A, the electronic component 101 may be formed by an integrated circuit manufacturing process. An interconnect structure 110 may be formed by a back end-of-line (BEOL) process to form a stack of metallization layers connected by vias. The topmost metallization layer may include one or more pads 111. One or more bumps (e.g., micro-bumps) 121 may be disposed on corresponding one or more pads 111. For the sake of clarity, pads 111 or bumps 121 are not labeled one by one in FIG. 1A or other similar drawings.

The electronic component 102 as shown in FIG. 1B is similar to the electronic component 101 as shown in FIG. 1A, the difference is that the electronic component omits the bumps (e.g., the bumps 121 as shown in FIG. 1A). The electronic component 103 as shown in FIG. 1C is similar to the electronic component 102 as shown in FIG. 1B, the difference is that the electronic component 103 omits the pads (e.g., the pads 111 as shown in FIG. 1A). The electronic component 102 and/or the electronic component 103 may be adapted for advanced packaging process, for example, a hybrid bonding process.

For electronic components (e.g., the electronic component 101, the electronic component 102, and/or the electronic component 103), the exposed conductors (e.g., the bumps 121 as shown in FIG. 1A, the pads 111 as shown in FIG. 1B, and/or the exposed portion of the topmost metallization layer 112 as shown in FIG. 1C) having small size could still be suitable for being performed an electron beam inspection. For example, a critical dimension (CD) of the exposed conductors could be as small as 10 micrometers (μm). That is, the size D1 of the exposed conductors could be large than or approximately equal to 10 μm, for example, 10 μm˜200 μm, 10 μm˜100 μm, 10 μm˜80 μm, 10 μm˜60 μm, 10 μm˜50 μm, 10 μm˜40 μm, or 10 μm˜30 μm, or 10 μm˜25 μm. That could be, the exposed conductor is capable to have a minimum critical dimension of 10 μm. A critical dimension of a conductor with approximately 40 μm is almost the limitation for a contact inspection by using a contact-based method (e.g., a probe card test or a probe pin test).

For electronic components, the exposed conductors having small pitch could still be suitable for being performed an electron beam inspection. For example, a pitch P1 between two adjacent exposed conductors could be as small as 3 μm. That is, the pitch P1 of the exposed conductors could be large than or approximately equal to 3 μm. In an embodiment, the pitch of the exposed conductors could be small than or approximately equal to 40 μm, for example, small than or approximately equal to 35 μm, 30 μm, or even 20 μm. A pitch with approximately 60 μm is almost the limitation for a contact inspection by using a contact-based method (e.g., a probe card test or a probe pin test).

As shown in FIGS. 2A and/or 2B, in a top view, the shape (e.g., the peripheral contour of vertical projection) of the exposed conductor 131, 132, 141, 142, 143, 151, 152, 161, 162, 163, 171, or 172 may be nearly or substantially circular, elliptical or polygonal (e.g., quadrilateral, hexagonal). In an embodiment, an electron beam inspection could be used to confirm whether the circuit between at least two exposed conductors is electrically conductive, for example, the circuit 138 between the exposed conductor 131 and the exposed conductor 132; the circuit 148 between the exposed conductor 141, the exposed conductor 142, and the exposed conductor 143; the circuit 158 between the exposed conductor 151 and the exposed conductor 152; the circuit 168 between the exposed conductor 161, the exposed conductor 162, and the exposed conductor 163; and/or, the circuit 178 between the exposed conductor 171 and the exposed conductor 172. It is worth noting that, circuits as shown in FIGS. FIGS. 2A and/or 2B are illustrated for example, circuits may include one or more conductive layers and one or more conductive vias (e.g., the frame regions with slash lines as shown in FIGS. 1A, 1B, and/or 1C) embedded in an insulator or a dielectric material (e.g., the blank region as shown in FIGS. 1A, 1B, and/or 1C) structurally.

In an embodiment, a minimum width D2 of the circuit could be as small as 2 μm. That is, the minimum width D2 of the circuit could be large than or approximately equal to 2 μm, for example, 2 μm˜5 μm, 2 μm˜10 μm, 2 μm˜50 μm, or 2 μm˜80 μm.

In an embodiment, for a chip, a die, or a semiconductor wafer including a plurality of die regions, the exposed conductors suitable for being performed an electron beam inspection are configured to correspond to a corner or an edge thereof.

In an embodiment, considering the quality and/or overall flow of the manufacturing process, and further considering the inspection quality efficiency, the exposed conductors could be configured correspond to one or more edges and/or one or more corners of the electronic component. One possible reason is that if a portion close to the corner or edge has a good process quality (especially for bonding process), the remaining portion away from the corner or edge should also have good process quality.

For example, as shown in FIG. 2A, the exposed conductors are configured correspond to at least one corner of the electronic component 104. The exposed conductors corresponding to a certain one corner are electrically connected by one or more circuits. For example, the exposed conductors 131, 132 corresponding to the corner C3 are electrically connected by the circuit 138; the exposed conductors 141, 142, 143 corresponding to the corner C4 are electrically connected by the circuit 148; the exposed conductors 151, 152 corresponding to the corner C5 are electrically connected by the circuit 158; and/or, the exposed conductors 161, 162, 163 corresponding to the corner C6 are electrically connected by the circuit.

For example, as shown in FIG. 2B, the exposed conductors 171, 172 are configured correspond to a certain one corner C7 of the electronic component 105. The exposed conductors 171, 172 are electrically connected by the circuit 178. In a top view, the pattern of the circuit 178 almost corresponds the edges E1, E2, E3, E4 of the electronic component 105, and could be referred as a ring.

FIGS. 3A and 3B illustrate side sectional views of a portion of an electronic package manufacturing process suitable for inspection of the disclosure. It is worth noting that, an electronic component for the electronic package manufacturing process as shown in FIGS. 3A and 3B may be similar to at least one of the electronic components 101, 102, 103 as shown in FIG. 1A to 1C, and/or an electronic component for the electronic package manufacturing process as shown in FIGS. 3A and 3B may be similar to at least one of the electronic components 104, 105 as shown in FIG. 2A to 2B; therefore, the description of the electronic component (e.g., an lower electronic component 301) corresponding to FIGS. 3A and 3B may or must refer to the description of the electronic components 101, 102, 103 corresponding to FIG. 1A to 1C, and/or the description of the electronic component (e.g., an upper electronic component 302) corresponding to FIGS. 3A and 3B may or must refer to the description of the electronic components 104, 105 corresponding to FIGS. 2A and/or 2B. For example, a top view or a bottom view of the upper electronic component 302 as shown in FIGS. 3A and 3B may have a simple representation as shown in FIGS. 2A and/or 2B.

In some embodiments of the present disclosure, electronic packages are sometimes constructed as semiconductor wafer and/or chip stacks, in which two or more of the semiconductor wafers and/or chips of the stack include integrated circuits (ICs). Some nonlimiting illustrative examples of such packages include: chip-on-wafer (CoW) packages, wafer-on-wafer (WoW) packages, chip-on-wafer-on-substrate (CoWoS) packages, integrated fan-out (InFO) packages, package-on-package (PoP) packages, system on integrated chips (SoIC) packages, and the like. In such packages, the ICs on different wafers and/or ICs of the stack are physically and electrically connected together by bonding the mating surfaces of bond pad metal on the respective wafers and/or ICs. In some approaches, two or more semiconductor chips may be bonded to a larger-area semiconductor chip or wafer. In some types of semiconductor wafer or chip stacks, an interposer wafer or chip may be inserted between two semiconductor wafers or chips that contain ICs. The interposer does not itself include any ICs, but the interposer includes one or more metallization layers, such as a metallization stack or stacks forming one or more redistribution layers (RDLs) for routing electrical power and/or signals between the ICs of the two semiconductor wafers or chips. The foregoing disclosures are merely some nonlimiting illustrative examples of semiconductor wafer and/or chip stacks.

In such semiconductor wafer and/or chip stacks, the conductor for bonding (e.g., a bonding pad) is typically formed in and/or embedded in an insulator or a dielectric material, which may be referred to as intermetal dielectric (IMD) or similar nomenclature. Material of a bonding pad typically includes copper, and connects with a bond pad via that electrically connects the bond pad metal to a metallization layer, to an aluminum pad, or connects with a corresponding circuit (e.g., an interconnect, a via, or a through-silicon via (TSV)). In one nonlimiting example, each semiconductor wafer or die has an IC or ICs formed by front end-of-line (FEOL) processing, which is followed by back end-of-line (BEOL) processing to form a stack of metallization layers connected by vias. The BEOL processing includes successive processes of IMD deposition and patterning, metal deposition/patterning or metal plating or the like to form each metallization layer and connecting vias. The topmost metallization layer then includes the bond pad metal and the connecting bond pad vias. The bonding of the bond pad metal of two wafers, chips, and/or interposers may for example employ thermal or thermocompression bonding, ultrasonic bonding, or the like.

As shown in FIG. 3A, a lower electronic component 301 includes a plurality of exposed conductors (e.g., exposed conductors 311 to 318 as shown in FIG. 3A, but not limited) disposed on an upper surface S1 thereof, and an upper electronic component 302 includes a plurality of exposed conductors (e.g., exposed conductors 323 to 3326 as shown in FIG. 3A, but not limited) disposed on a lower surface S2 thereof. The upper surface S1 of the lower electronic component 301 and the lower surface S2 of the upper electronic component 302 face each other, so as to be suitable for performing a subsequent bonding process.

Before performing a bonding process for bonding the lower electronic component 301 and the upper electronic component 302, an electron beam inspection could be performed by an electron beam apparatus 91, to confirm the electrical status one or more circuits (e.g., to confirm a corresponding circuit is open, short, break, or leakage).

For example, as shown in FIG. 3A, in a conceived structural or layout design, the exposed conductor 311 is electrically connected to the exposed conductor 314, the exposed conductor 312 is electrically connected to the exposed conductor 313, the exposed conductor 315 is electrically connected to the exposed conductor 318, and the exposed conductor 316 is electrically connected to the exposed conductor 317; and, the exposed conductor 313, the exposed conductor 314, the exposed conductor 315, and the exposed conductor 316 are electrically separated from each other. Therefore, through the above-mentioned electron beam inspection, the aforementioned electrical status could be confirmed.

It is worth noting that, the structure as shown in FIG. 3A may correspond to the conceived structure or layout design, for example, a circuit 331 between the exposed conductor 311 and the exposed conductor 314, a circuit 332 between the exposed conductor 312 and the exposed conductor 313, a circuit 333 between the exposed conductor 315 and the exposed conductor 318, and a circuit 334 between the exposed conductor 316 and the exposed conductor 317 provide a conceived electrical connection.

In an unexpected but possible structure (not shown in the drawings), a circuit of the lower electronic component 301 for providing a conceived electrical connection originally may be break. Therefore, a dummy component structurally similar to the upper electronic component 302 could be provided for replacing thereto for the subsequent bonding process. As such, a cost of the electronic package manufacturing process may be reduced, and/or the quality and/or overall flow of the electronic package manufacturing process may be remained or improved.

In an embodiment not shown in the drawing, an electron beam inspection could be performed to the upper electronic component 302, for confirming the electrical status one or more circuits (e.g., to confirm a corresponding circuit is open, short, break, or leakage).

In an embodiment, before performing the bonding process for bonding the lower electronic component 301 and the upper electronic component 302, an electron beam inspection could be performed to the upper electronic component 302 and the lower electronic component 301 by an electron beam apparatus 91, for confirming the electrical status one or more circuits

As shown in FIG. 3B, after the lower electronic component 301 and the upper electronic component 302 are directly connected or partially connected (e.g., post-bonded) by performing the bonding process, an electron beam inspection could be performed by an electron beam apparatus 91, to confirm the electrical property of one or more circuits (e.g., to confirm a corresponding circuit is open, short, break, or leakage). That is, during and/or after the bonding process, an electron beam inspection could be performed.

For example, as shown in FIG. 3B, in a conceived structural or layout design, the exposed conductor 311 is electrically connected to the exposed conductor 312 by corresponding circuits 331, 332 and conductors 313, 314 of the lower electronic component 301 and a corresponding circuit 342 and conductors 323, 324 of the upper electronic component 302, and the exposed conductor 318 is electrically connected to the exposed conductor 317 by corresponding circuits 333, 334 and conductors 316, 315 of the lower electronic component 301 and a corresponding circuit 344 and conductors 326, 325 of the upper electronic component 302. Therefore, through the above-mentioned electron beam inspection, the aforementioned electrical status could be confirmed.

For more example, the upper electronic component 302 could be disposed on the lower electronic component 301, and a conductor of the lower electronic component 301 and a conductor of the upper electronic component 302 may be temporarily bonded by heating. The aforementioned temporary bonding step could be referred as a post-bonding step. Then, an electron beam inspection could be performed by the electron beam apparatus 91, to confirm the electrical property between the aforementioned conductors. If the electrical property between the aforementioned conductors corresponds to a conceived design, a further bonding step (e.g., a thermocompression bonding step and/or an ultrasonic bonding step) could be performed for to making the bond between the upper electronic component 302 and the lower electronic component 301 stronger.

It is worth noting that, the structure as shown in FIG. 3B may correspond to the conceived structure or layout design.

In an unexpected but possible structure (not shown in the drawings), an electrical bonding region between the lower electronic component 301 and the upper electronic component 302 for providing a conceived electrical connection originally may be break, possibly due to a manufacturing process error (e.g., shift, rotation, misalignment or warpage). Therefore, a rework process could be provided or a recipe of the manufacturing process could be tuned. As such, a cost of the electronic package manufacturing process may be reduced, and/or the quality and/or overall flow of the electronic package manufacturing process may be remained or improved.

It is worth noting that, only one upper electronic component 302 is shown in FIGS. 3A and 3B, but the disclosure is not limited thereto. For example, one or more upper electronic components the same or similar to the upper electronic component 302 could be disposed on the lower electronic component 301. If there are a plurality of upper electronic components, two of the upper electronic components may be homogeneous electronic components or may be heterogeneous electronic components. For example, the upper electronic component 302 may be an application-specific integrated circuit (ASIC), a dynamic random access memory (DRAM), a static random access memory (SRAM), a system on chip (SoC), a high performance computing (HPC), a large scale integration (LSI), or a stack thereof, but the disclosure is not limited thereto.

In an embodiment, considering the electron beam apparatus 91 (e.g., a size of the electron gun) and/or detection method (e.g., scattered electrons and/or method for image capture) used or performed in the inspection process, a distance D3 of the edge of the upper electronic component 302 and the conductor for performing the inspection process of the lower electronic component 301 is larger than or approximately equal to 200 μm.

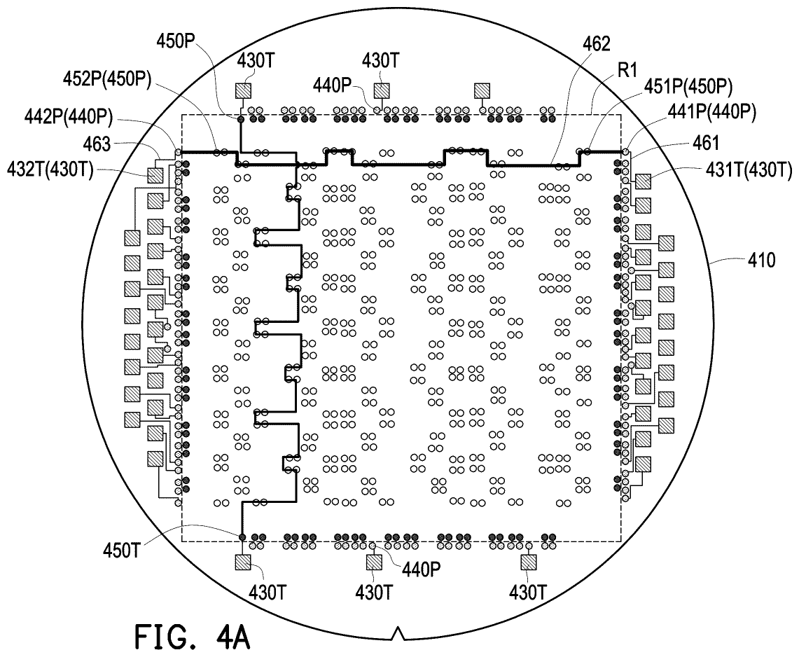

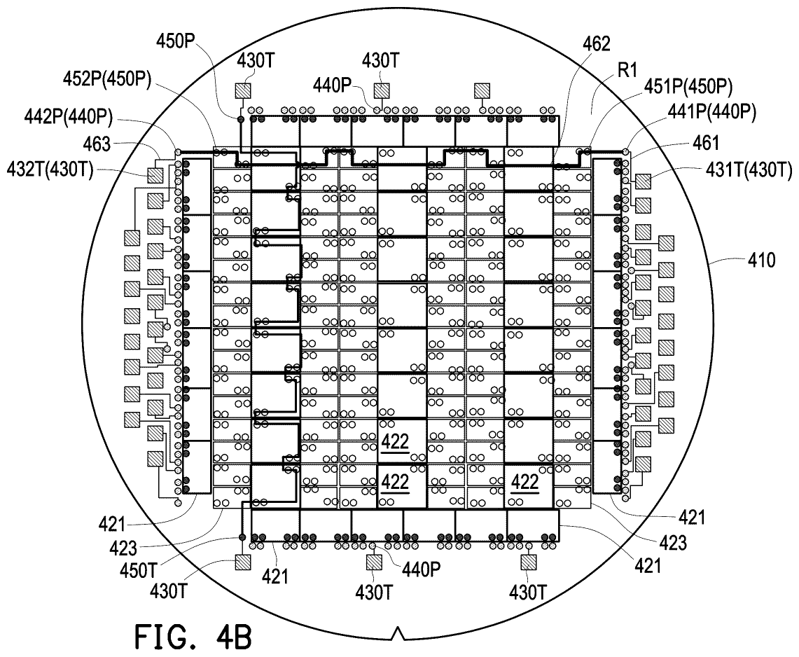

FIGS. 4A and 4B illustrate top views of a portion of an electronic package manufacturing process suitable for inspection of the disclosure. It is worth noting that, the electronic package manufacturing process as shown in FIGS. 4A and 4B may be similar to the electronic package manufacturing process as shown in FIGS. 3A and 3B; therefore, the description of the electronic package manufacturing process corresponding to FIGS. 4A and 4B may or must refer to the description of the electronic package manufacturing process corresponding to FIGS. 3A and 3B. For example, the side sectional views as shown in FIGS. 3A and 3B may be a simple representation of the top views as shown in FIGS. 4A and 4B, respectively. For example, a side sectional view of the lower electronic component 410 as shown in FIG. 4A may correspond to the side sectional view of the lower electronic component 301 as shown in FIG. 3A. For example, a side sectional view of the stack of the lower electronic component 410 and one of the upper electronic components 421, 422, 423 as shown in FIG. 4B may correspond to the side sectional view of the stack of the lower electronic component 301 and the upper electronic component 302 as shown in FIG. 3B.

As shown in FIG. 4A, a lower electronic component 410 may be a wafer including a plurality of exposed conductors and circuits. It is worth noting that, for the sake of clarity, conductors (e.g., the exposed conductors) or circuits are not drawn and/or labeled one by one in FIG. 4A or other similar drawings. The exposed conductors are disposed on an upper surface. One or more circuits is/are electrically connected to one or more corresponding exposed conductors. In a top view, the lower electronic component 410 has a bonding area R1 for the subsequent bonding process.

In an embodiment, a wafer being the lower electronic component 410 is a system on wafer (SoW), an interposer wafer, or a redistribution layer (RDL) wafer, but the disclosure is not limited thereto. In an embodiment, the exposed conductors are conductive bumps (e.g., the bumps 121 as shown in FIG. 1A), conductive pads (e.g., the pad 111 as shown in FIG. 1B) or a portion of the metallization layer (the exposed portion of the topmost metallization layer 112 as shown in FIG. 1C), but the disclosure is not limited thereto.

In an embodiment, the plurality of exposed conductors of the lower electronic component 410 includes a plurality of first conductors 430T, 440P and a plurality of second conductors 450P. In a top view, the first conductors 430T are located outside the bonding area R1, and/or the first conductors 430T formally surround the bonding area R1. In a top view, some of the second conductors 440P are located outside the bonding area R1, and other second conductors 450P are located inside the bonding area R1. The first conductors 430T formally surround the second conductors 440P, 450P.

In an embodiment, a critical dimension of the first conductor 430T is larger than a critical dimension of the second conductor 440P, 450P. In an embodiment, the critical dimension of the first conductor 430T could be as small as 45 μm. That is, the size of the first conductor 430T could be large than or approximately equal to 45 μm, for example, 45 μm˜200 μm, 45 μm˜100 μm, 45 μm˜80 μm, 45 μm˜60 μm, or 45 μm˜50 μm.

In an embodiment, the first conductor 430T is referred as a test conductor, and/or the second conductor 440P, 450P is referred as a probe conductor, but the disclosure is not limited thereto.

The first conductor 430T with a larger critical dimension (comparing with the second conductor) may be suitable for directing the electron beam apparatus 91 theretoward. For example, comparing with the second conductor 440P, 450P, the first conductor 430T with a larger critical dimension has a larger effective high-energy electron acceptance/bombardment area. As such, an inspection limit or an inspection quality (e.g., precision or accuracy) could be improved.

In an embodiment, the electronic component (e.g., the lower electronic component 410) could be partially or fully scanned to obtain a corresponding inspecting image.

Taking the first conductors 431T, 432T (two of the first conductors 430T), the second conductors 441P, 442P (two of the second conductors 440P located outside the bonding area R1), and the second conductors 451P, 452P (two of the second conductors 450P located inside the bonding area R1) for example, as shown in FIG. 3A, in a conceived structural or layout design, a first conductors 431T, 432T and the second conductors 441P, 442P, 451P, 452P may be electrically connected by one or more corresponding circuits 461, 462, 463. The electron beam could be directed toward the first conductor 431T; and then, the electronic component 410 could be partially scanned focus on at least one of the second conductors 441P, 442P, 451P, 452P and/or the first conductor 432T to obtain corresponding one or more inspecting images, to confirm the electrical property (e.g., electrical conductivity) between the first conductor 431T and one or more other conductors being scanned.

In an embodiment, a circuit that substantially or almost crosses the bonding area R1 of the lower electronic component 410 may be served as a power circuit, for example, referred as a high-potential power supply trace (Vdd), a low-potential power supply trace (Vss), or a grounding trace (Vg or Vgg), but the disclosure is not limited thereto.

In an embodiment, the aforementioned inspection focused on the redistribution of corresponding one or more circuits (e.g., an interconnect, a via, a through-silicon via (TSV), or a connection therebetween) is referred as a redistribution wafer acceptance testing (RWAT), but the disclosure is not limited thereto. A redistribution wafer acceptance testing (RWAT) could be performed before the aforementioned bonding process, but the disclosure is not limited thereto.

As shown in FIG. 4B, a plurality of upper electronic component could be disposed on the lower electronic component 410. The plurality of upper electronic components may include one or more first upper electronic components 421, one or more second upper electronic components 422, and one or more third upper electronic components 423. In an embodiment, the first upper electronic component 421 is an input/output (I/O) chip; a second upper electronic component 422 is a system on chip (SoC); and, a third upper electronic component 423 is a stacked memory, for example, a high bandwidth memory (HBM), but the disclosure is not limited thereto. It is worth noting that, for the sake of clarity, upper electronic components 421, 422, 423 are not drawn and/or labeled one by one in FIG. 4B or other similar drawings.

In an embodiment, an electron beam inspection the same or similar to the description corresponding to FIG. 3B could be performed, to confirm the electrical property between at least one of the upper electronic components 421, 422, 423 and the lower electronic component 410, or between at least two of the upper electronic components 421, 422, 423.

In an embodiment, the exposed conductors for bonding of one of the upper electronic components 421, 422, 423 are configured correspond to at least one corner or edge thereof. For example, the exposed conductors for bonding of one of the upper electronic components 421, 422, 423 are configured correspond to at least two corners thereof. For example, the exposed conductors for bonding of one of the upper electronic components 421, 422, 423 are configured correspond to two diagonal corners thereof. For example, the exposed conductors for bonding of one of the upper electronic components 421, 422, 423 are configured correspond to two corners corresponding to the same edge thereof.

In an embodiment, the aforementioned inspection focused on the electrical property (e.g., electrical conductivity) between the bonded lower electronic component and upper electronic component is referred as a jointed wafer acceptance testing (JWAT), but the disclosure is not limited thereto. That is, a joint wafer acceptance testing (JWAT) could be performed after the aforementioned bonding process, but the disclosure is not limited thereto.

In an embodiment, a bonded structure (e.g., a structure as shown in FIGS. 3B and/or 4B) could be performed by a further process, for example, a package process (e.g., a molding process, or an encapsulating process), but the disclosure is not limited thereto. One or more further inspection or testing processes, for example, an assembly test (AST), a final test (FT), and/or a system level test (SLT) could be performed after the aforementioned bonding process.

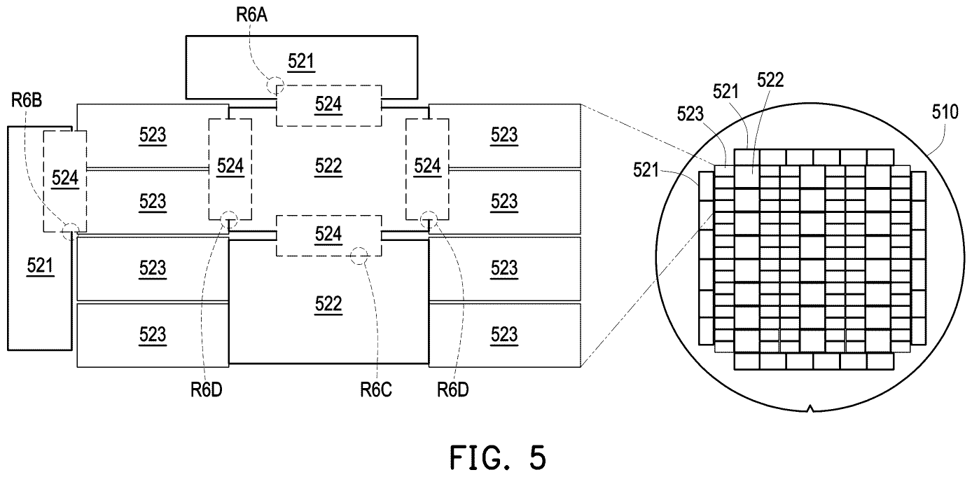

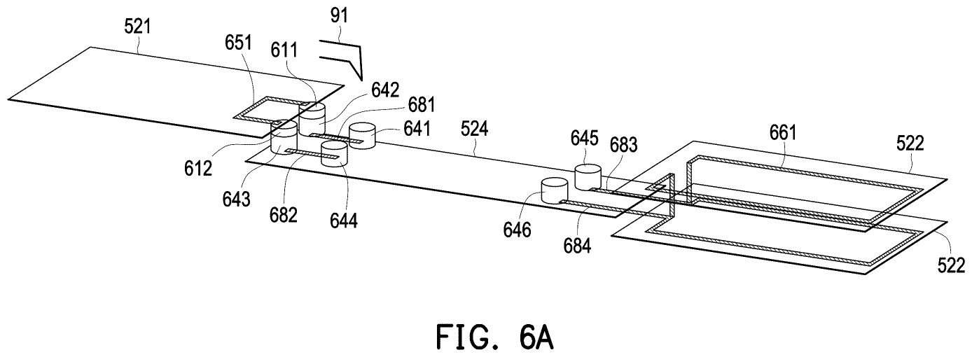

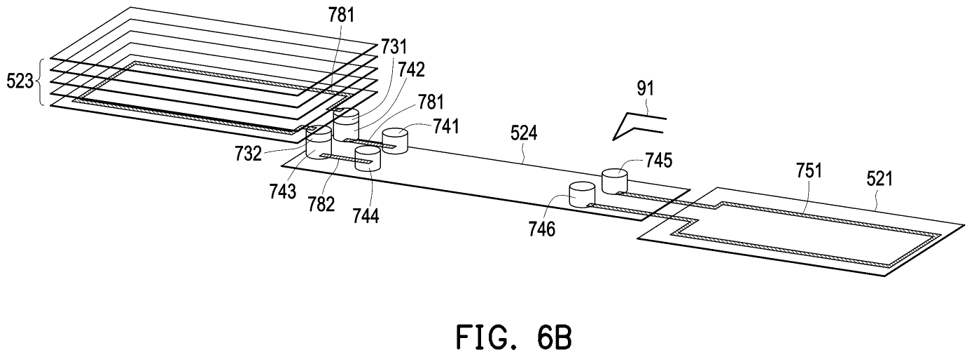

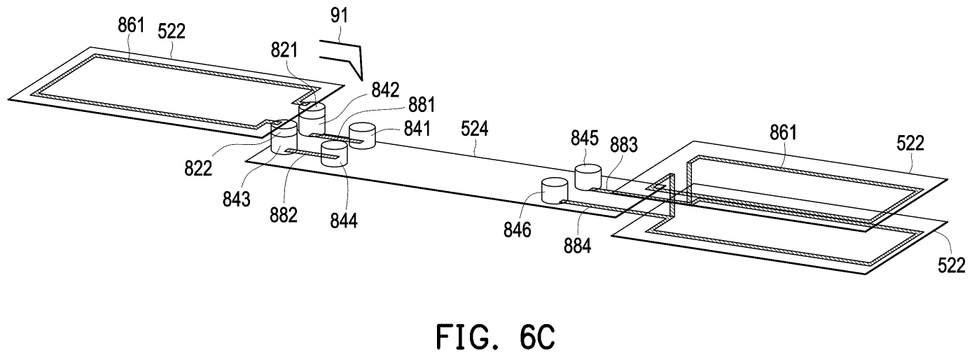

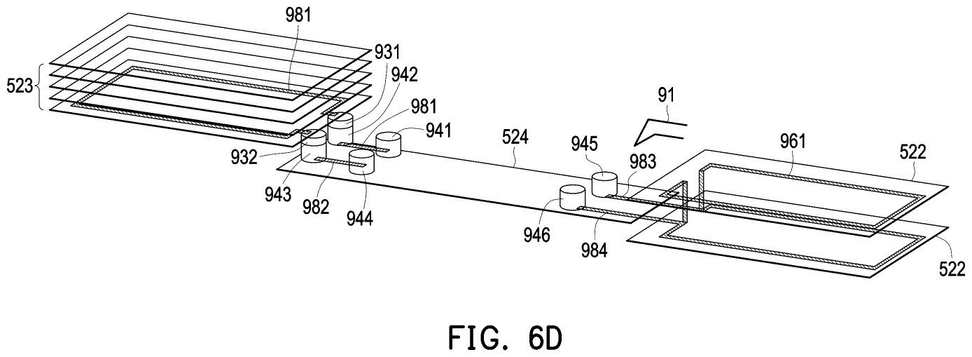

FIG. 5 illustrates a top view of an electronic package suitable for inspection of the disclosure. FIGS. 6A to 6D illustrate perspective views of a portion of an electronic package suitable for inspection of the disclosure. For example, FIG. 6A may be a perspective view corresponding to the region R6A as shown in FIG. 5; FIG. 6B may be a perspective view corresponding to the region R6B as shown in FIG. 5; FIG. 6C may be a perspective view corresponding to the region R6C as shown in FIG. 5; and/or, FIG. 6D may be a perspective view corresponding to the region R6D as shown in FIG. 5.

Referring to FIG. 5 a wafer being the lower electronic component 510 is a carrier wafer for carrying one or more components disposed thereabove, but the disclosure is not limited thereto. A plurality of upper electronic components could be disposed on the lower electronic component 510. The plurality of upper electronic components may include one or more first upper electronic components 521, one or more second upper electronic components 522, one or more third upper electronic components 523, and one or more fourth upper electronic components 524. In an embodiment, the first upper electronic component 521 is an input/output (I/O) chip; a second upper electronic component 522 is a system on chip (SoC); a third upper electronic component 523 is a stacked memory, for example, a high bandwidth memory (HBM); and, a fourth upper electronic component 524 is a large scale integration (LSI), but the disclosure is not limited thereto.

In a direction substantially parallel to thickness, two of the upper electronic components could be partially overlapped, for being bond and electrically connected.

For example, as shown in FIGS. 5 and 6A, the fourth upper electronic component 524 could be partially overlapped to the first upper electronic component 521. An inspection process could be performed by an electron beam apparatus 91, to confirm the bonding quality or the electrical property of the routing including: the conductors 641, 642, 643, 644 and the circuits 681, 682 of the fourth upper electronic component 524; and, the conductors 611, 612 and the circuit 651 of the first upper electronic component 521.

For example, as shown in FIGS. 5 and 6A, the fourth upper electronic component 524 could be partially overlapped to the second upper electronic components 522. An inspection process could be performed by an electron beam apparatus (not shown, for example, the same or similar to the electron beam apparatus 91), to confirm the bonding quality or the electrical property of the routing including: the conductors 646, 645 and the circuits 683, 684 of the fourth upper electronic component 524; and, the circuit 661 of the second upper electronic components 522.

For example, as shown in FIGS. 5 and 6B, the fourth upper electronic component 524 could be partially overlapped to the first upper electronic component 521. An inspection process could be performed by an electron beam apparatus 91, to confirm the bonding quality or the electrical property of the routing including: the conductors 745, 746 and the circuit of the fourth upper electronic component 524; and, the circuits 751 of the first upper electronic component 521.

For example, as shown in FIGS. 5 and 6B, the fourth upper electronic component 524 could be partially overlapped to the third upper electronic component 523. An inspection process could be performed by an electron beam apparatus (not shown, for example, the same or similar to the electron beam apparatus 91), to confirm the bonding quality or the electrical property of the routing including: the conductors 741, 742, 743, 744 and the circuits 781, 782 of the fourth upper electronic component 524; and, the conductors 731, 732 and the circuit 781 of the third upper electronic component 523.

For example, as shown in FIGS. 5 and 6C, the fourth upper electronic component 524 could be partially overlapped to the second upper electronic component 522. An inspection process could be performed by an electron beam apparatus 91, to confirm the bonding quality or the electrical property of the routing including: the conductors 841, 842, 843, 844 and the circuits 881, 882 of the fourth upper electronic component 524; and, the conductors 821, 822 and the circuit 861 of the second upper electronic components 522.

For example, as shown in FIGS. 5 and 6C, the fourth upper electronic component 524 could be partially overlapped to the second upper electronic components 522. An inspection process could be performed by an electron beam apparatus (not shown, for example, the same or similar to the electron beam apparatus 91), to confirm the bonding quality or the electrical property of the routing including: the conductors 845, 846 and the circuits 883, 884 of the fourth upper electronic component 524; and, the circuit 861 of the second upper electronic components 522.

For example, as shown in FIGS. 5 and 6D, the fourth upper electronic component 524 could be partially overlapped to the second upper electronic components 522. An inspection process could be performed by an electron beam apparatus 91, to confirm the bonding quality or the electrical property of the routing including: the conductors 945, 946 and the circuits 983, 984 of the fourth upper electronic component 524; and, the circuit 961 of the second upper electronic components 522.

For example, as shown in FIGS. 5 and 6D, the fourth upper electronic component 524 could be partially overlapped to the third upper electronic component 523. An inspection process could be performed by an electron beam apparatus (not shown, for example, the same or similar to the electron beam apparatus 91), to confirm the bonding quality or the electrical property of the routing including: the conductors 941, 942, 943, 944 and the circuits 981, 982 of the fourth upper electronic component 524; and, the conductors 931, 932 and the circuit 981 of the third upper electronic component 523.

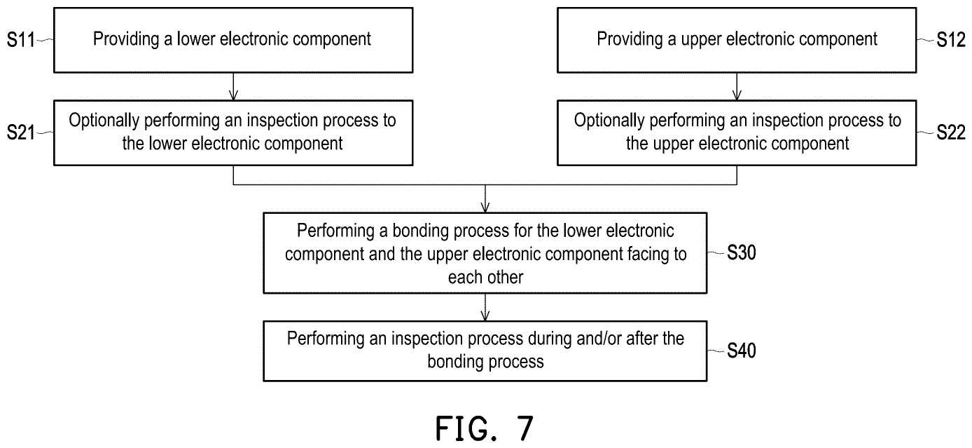

FIG. 7 illustrates a portion of flow for a manufacturing method of an electronic component of the disclosure. The manufacturing method may include the following steps.

The step S11 includes providing a lower electronic component. In an embodiment, the lower electronic component is referred as a first electronic component.

The step S21 is an optional step and includes performing an inspection process to the lower electronic component. In an embodiment, the inspection process to the lower electronic component is referred as a first inspection process.

The step S12 includes providing an upper electronic component. In an embodiment, the upper electronic component is referred as a second electronic component.

The step S22 includes is an optional step and includes performing an inspection process to the upper electronic component. In an embodiment, the inspection process to the upper electronic component is referred as a second inspection process.

The step S30 includes performing a bonding process for the lower electronic component and the upper electronic component facing to each other.

The step S40 is an optional step and includes performing an inspection process during and/or after the bonding process.

It is worth noting that, at least one of the step S21, the step S22, and the step S24 is performed.

In accordance with some embodiments of the present disclosure, a method includes: providing a first electronic component; providing a second electronic component; performing a bonding process to bond the first electronic component and the second electronic component; and performing an inspection process during and/or after the bonding process, wherein the inspection process includes a contactless inspection process. In an embodiment, the first electronic component and the second electronic component are disposed face to face for performing the bonding process; the first electronic component includes a first exposed conductor for the inspection process; and a distance between the first exposed conductor of the first electronic component and an edge of the second electronic component closest to the first exposed conductor is larger than or approximately equal to 200 μm. In an embodiment, the first electronic component includes a plurality of first exposed conductors and a plurality of second exposed conductors, wherein: the second electronic component is disposed on at least two of the plurality of second exposed conductors for performing the bonding process; and the inspection process is performed by at least one of the plurality of first exposed conductors non-overlapped to the second electronic component. In an embodiment, the plurality of first exposed conductors are disposed surrounding the plurality of second exposed conductors. In an embodiment, a critical dimension of the plurality of first exposed conductors is larger than a critical dimension of the plurality of second exposed conductors. In an embodiment, the contactless inspection process includes confirming an electrical property between two of the plurality of first exposed conductors and the plurality of second exposed conductors through an inspecting image. In an embodiment, the second electronic component includes a plurality of third exposed conductors, wherein: the second electronic component is disposed on the first electronic component, such that the plurality of third exposed conductors and a portion of the plurality of second exposed conductors correspond to each other, for performing the bonding process; and the plurality of third exposed conductors are configured correspond to at least one corner or edge of the second electronic component. In an embodiment, the plurality of third exposed conductors are configured correspond to two diagonal corners of the second electronic component. In an embodiment, the plurality of first exposed conductors are configured correspond to at least one corner or edge of the first electronic component. In an embodiment, a space between adjacent two of the plurality of second exposed conductors is capable to have a minimum distance of 3 μm.

In accordance with some embodiments of the present disclosure, a method includes: providing a first electronic component; providing a second electronic component; performing a bonding process to bond the first electronic component and the second electronic component; and performing an inspection process (e.g., a third inspection process) in a low-pressure environment during and/or after the bonding process, wherein a gas pressure in the low-pressure environment is less than or approximately equal to 100 Pa. In an embodiment, the inspection process (e.g., the third inspection process) is performed by an electronic beam inspection system. In an embodiment, the inspection process (e.g., the third inspection process) includes directing an electron beam toward at least one conductive portion of the first electronic component and/or the second electronic component. In an embodiment, the at least one conductive portion includes an exposed portion of the first electronic component and/or the second electronic component. In an embodiment, the method further includes: performing an inspection process (e.g., a first inspection process) to the first electronic component before performing the bonding process in the low-pressure environment. In an embodiment, the method further includes: performing an inspection process (e.g., a second inspection process) to the second electronic component before performing the bonding process in the low-pressure environment.

In accordance with some embodiments of the present disclosure, a method includes: providing a first electronic component; providing a second electronic component; performing a bonding process to bond the first electronic component and the second electronic component; and performing an inspection process, wherein the inspection process includes determining an electrical property between a first conductor and a second conductor of the first electronic component or the second electronic component by an inspecting image corresponding to the second conductor. In an embodiment, during the inspecting image being obtained, there is substantially no voltage difference between the first conductor and the second conductor. In an embodiment, the second conductor has a minimum critical dimension of 10 μm. In an embodiment, the method further includes: performing a package process after the bonding process and the inspection process.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
providing a first electronic component;
providing a second electronic component;
performing a bonding process to bond the first electronic component and the second electronic component; and
performing an inspection process during or after the bonding process, wherein the inspection process comprises a contactless inspection process.

2. The method of claim 1, wherein:
the first electronic component and the second electronic component are disposed face to face for performing the bonding process;
the first electronic component comprises a first exposed conductor for the inspection process; and
a distance between the first exposed conductor of the first electronic component and an edge of the second electronic component closest to the first exposed conductor is larger than or approximately equal to 200 μm.

3. The method of claim 1, wherein the first electronic component comprises a plurality of first exposed conductors and a plurality of second exposed conductors, wherein:
the second electronic component is disposed on at least two of the plurality of second exposed conductors for performing the bonding process; and
the inspection process is performed by at least one of the plurality of first exposed conductors non-overlapped to the second electronic component.

4. The method of claim 3, wherein the plurality of first exposed conductors are disposed surrounding the plurality of second exposed conductors.

5. The method of claim 3, wherein a critical dimension of the plurality of first exposed conductors is larger than a critical dimension of the plurality of second exposed conductors.

6. The method of claim 3, wherein the contactless inspection process comprises confirming an electrical property between two of the plurality of first exposed conductors and the plurality of second exposed conductors through an inspecting image.

7. The method of claim 3, wherein the second electronic component comprises a plurality of third exposed conductors, wherein:
the second electronic component is disposed on the first electronic component, such that the plurality of third exposed conductors and a portion of the plurality of second exposed conductors correspond to each other, for performing the bonding process; and
the plurality of third exposed conductors are configured correspond to at least one corner or edge of the second electronic component.

8. The method of claim 7, wherein the plurality of third exposed conductors are configured correspond to two diagonal corners of the second electronic component.

9. The method of claim 3, wherein the plurality of first exposed conductors are configured correspond to at least one corner or edge of the first electronic component.

10. The method of claim 3, wherein a space between adjacent two of the plurality of second exposed conductors is capable to have a minimum distance of 3 μm.

11. A method, comprising:
providing a first electronic component;
providing a second electronic component;
performing a bonding process to bond the first electronic component and the second electronic component; and
performing an inspection process in a low-pressure environment during or after the bonding process, wherein a gas pressure in the low-pressure environment is less than or approximately equal to 100 Pa.

12. The method of claim 11, wherein the inspection process is performed by an electronic beam inspection system.

13. The method of claim 11, wherein the inspection process comprises directing an electron beam toward at least one conductive portion of the first electronic component or the second electronic component.

14. The method of claim 13, wherein the at least one conductive portion comprises an exposed portion of the first electronic component or the second electronic component.

15. The method of claim 11, further comprising:
performing an inspection process to the first electronic component before performing the bonding process in the low-pressure environment.

16. The method of claim 11, further comprising:
performing an inspection process to the second electronic component before performing the bonding process in the low-pressure environment.

17. A method, comprising:
providing a first electronic component;
providing a second electronic component;
performing a bonding process to bond the first electronic component and the second electronic component; and
performing an inspection process, wherein the inspection process comprises determining an electrical property between a first conductor and a second conductor of the first electronic component or the second electronic component by an inspecting image corresponding to the second conductor.

18. The method of claim 17, during the inspecting image being obtained, there is substantially no voltage difference between the first conductor and the second conductor.

19. The method of claim 17, wherein the second conductor has a minimum critical dimension of 10 μm.

20. The method of claim 17, further comprising:
performing a package process after the bonding process and the inspection process.
